(19) United States
(12) Patent Application Publication
(10) Pub. No.: US 2010/0270603 A1
(43) Pub. Date: Oct. 28, 2010

(54) SEMICONDUCTOR DEVICE AND METHOD OF MANUFACTURING THE SAME

(75) Inventor: Chi Hwan JANG, Icheon-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/495,544

(22) Filed: Jun. 30, 2009

(30) Foreign Application Priority Data
Apr. 22, 2009 (KR) 10-2009-0035174

(51) Int. Cl. H01L 27/10; H01L 21/336; H01L 21/3205

(52) U.S. Cl. 257/296; 438/586; 257/E27.071; 257/E21.409; 257/E21.295

(57) ABSTRACT

A semiconductor device comprises gates comprising a first conductive layer, landing plug contacts formed adjacent to the gate and formed of a second conductive layer, a bit line formed over the landing plug contacts and formed of a third conductive layer, and storage electrode contacts formed over the landing plug contacts and the bit line and formed of a fourth conductive layer. The first conductive layer, the second conductive layer, the third conductive layer, and the fourth conductive layer are made of the same material.

### CROSS-REFERENCE TO RELATED APPLICATION

The present application claims priority to Korean patent application number 10-2009-0035174, filed on Apr. 22, 2009, which is incorporated by reference in its entirety.

### BACKGROUND OF THE INVENTION

The present invention relates to a semiconductor device and a method of manufacturing the same.

A semiconductor device is manufactured through a process of implanting an impurity into a specific region within a silicon wafer or depositing/etching a new material on the specific region within the silicon wafer. A representative example of the semiconductor device may include a semiconductor memory device. The semiconductor memory device includes a number of unit cells each including capacitors and transistors. The capacitor (in the case of DRAM) is used to temporarily store data. The transistor is used to transfer data between a bit line and a capacitor in response to a control signal (a word line). The transistor includes three regions; a gate, a source, and a drain. Electric charges move between the source and the drain in response to a control signal input to the gate. The movement of electric charges between the source and the drain is carried out through a channel region.

Polysilicon has been chiefly used as the material of the gate and the bit line of the semiconductor device. A metal gate using tungsten (W) has recently been commercialized, resulting in many improvements including a reduction in the resistance of the gate.

Research is being carried out in order to further improve the speed of a semiconductor device by reducing resistance. However, technologies posterior to the gate and the bit line using tungsten (W) have not been commercialized, and there is a need for the development of a gate and a bit line using new materials. Further, the material (i.e., polysilicon or tungsten) used in a landing plug contact has limitations in resistance reduction because it requires a high aspect ratio.

In the current gate structure (including a gate electrode and a gate hard mask) of a semiconductor device, the gate electrode is formed to protrude from the surface of a semiconductor substrate (a silicon substrate) by a specific height. Thus, the gate structure is formed at the height of about 100 nm over the semiconductor substrate. Accordingly, the landing plug contacts formed on the sides of the gate structure and coupled to the semiconductor substrate are also formed at the height of about 100 nm over the semiconductor substrate. Consequently, there are problems in that the resistance of the landing plug contact is high and a gate Self-Aligned-Contact (SAC) fail frequently occurs with the smaller design rule of a semiconductor device.

### BRIEF SUMMARY OF THE INVENTION

Various embodiments of the invention are directed to providing a semiconductor device and a method of manufacturing the same, which is capable of enhancing the processing speed of a semiconductor device, reducing the power consumption of a semiconductor device, and securing a sufficient process margin by reducing the resistance of gates, a bit line, and landing plug contacts.

According to an embodiment of the present invention, a semiconductor device comprises gates comprising a first conductive layer, landing plug contacts formed adjacent to the gate and formed of a second conductive layer, a bit line formed over the landing plug contacts and formed of a third conductive layer, and storage electrode contacts formed over the landing plug contacts and the bit line and formed of a fourth conductive layer. The first conductive layer, the second conductive layer, the third conductive layer, and the fourth conductive layer are made of the same material. Accordingly, since the resistance of the gates, the bit line, and the landing plug contacts is reduced, the processing speed of a semiconductor device can be increased and the power consumption of a semiconductor device can be reduced. Further, since a process of manufacturing a device is simplified, a process margin can be improved.

Further, the first conductive layer, the second conductive layer, the third conductive layer, and the fourth conductive layer are made of metal comprising copper (Cu). Accordingly, resistance can be minimized.

Further, each of the gates comprises the first conductive layer filled in a recess of a semiconductor substrate, and a gate hard mask layer formed on the first conductive layer. Accordingly, since the landing plug contacts can be thinly formed as compared with a conventional gate including a polysilicon layer, the resistance of the landing plug contacts can be reduced.

Further, the semiconductor device further comprises a gate oxide layer formed on a surface of the recess, and a diffusion barrier layer formed on the gate oxide layer. Accordingly, the gate oxide layer can protect a surface of the semiconductor substrate made of a silicon material, and the diffusion barrier layer can prevent a gate material from diffusing into the gate oxide layer, so a fail rate of semiconductor devices can be reduced.

Further, the diffusion barrier layer is made of any one of an oxide-based (MoOx, ZrOx, TaOx, TiOx, RuOx, and CrOx) material, a nitride-based (MoNx, ZrNx, TaNx, TiNx, RuNx, and CrNx) material, and a metal-based (Mo, Zr, Ta, Ti, Ru, Cr, and Hf) material. Accordingly, the material of a gate made of a metal material can be prevented from diffusing outside.

Further, the height of a top surface of the first conductive layer is identical to that of a top surface of the semiconductor substrate, and so the thickness of the gate hard mask layer becomes identical to that of the landing plug contacts. Accordingly, the thickness of the landing plug contacts can be decreased.

Further, the semiconductor device further comprises a dielectric interlayer configured to insulate the first conductive layer, the bit line, and capacitors on the respective storage electrode contacts from one another. Accordingly, the insulation performance between the respective elements can be enhanced.

Meanwhile, according to another embodiment of the present invention, a method of manufacturing a semiconductor device comprises forming gates in a semiconductor substrate, the gates comprising a first conductive layer, forming landing plug contacts over a semiconductor substrate adjacent to the gates, the landing plug contacts being formed of a second conductive layer, forming a bit line over some of the landing plug contacts, the bit line being made of a third conductive layer, and forming storage electrode contacts over respective landing plug contacts which do not have the bit line formed thereover and belong to the landing plug contacts, the storage electrode contacts being made of a fourth conductive layer. Accordingly, since the resistance of the gates, the bit line, and the landing plug contacts is reduced, the processing speed of a semiconductor device can be increased and the power consumption of a semiconductor device can be reduced.

Further, the first conductive layer, the second conductive layer, the third conductive layer, and the fourth conductive layer are made of the same material. Accordingly, since the process is simplified, a process margin can be improved.

Further, the first conductive layer, the second conductive layer, the third conductive layer, and the fourth conductive layer are made of metal comprising copper (Cu). Accordingly, the resistance of the elements can be minimized.

Further, the forming-gates-in-a-semiconductor-substrate uses a method of forming a recess gate, comprising filling the first conductive layer in the recesses of the semiconductor substrate and forming a gate hard mask layer on the first conductive layer. Accordingly, the height of a gate structure, protruding from the semiconductor substrate, can be minimized.

Further, the method further comprises forming a gate oxide layer on the entire surface of the semiconductor substrate, including the recesses, and forming a diffusion barrier layer on the gate oxide layer. Accordingly, the gate oxide layer can protect a surface of the semiconductor substrate made of a silicon material, and the diffusion barrier layer can prevent a gate material from diffusing into the gate oxide layer, so a fail rate of semiconductor devices can be reduced.

Further, the forming-a-diffusion-barrier-layer-on-the-gate-oxide-layer is carried out by a Chemical Vapor Deposition (CVD), Metal-Organic CVD (MOCVD), or Atomic Layer Deposition (ALD) method. Accordingly, an oxide- or nitride-based diffusion barrier layer can be easily deposited.

Further, the forming-a-gate-oxide-layer is carried out by any one of a CVD method using a high-K material or a PZT material, such as SiO₂, ONO, HfOx, or ZrOx, a method of heating the semiconductor substrate within a furnace, and a method of depositing a high-K material, such as Zr or Hf, on a surface of the recesses using ALD and then naturally oxidizing the deposited high-K material. Accordingly, the diffusion barrier layer and the gate oxide layer may be formed more solidly.

Further, the first conductive layer is filled in the recesses so that a top surface of the first conductive layer has the same height as a top surface of the semiconductor substrate. Accordingly, the height of the gate hard mask layer, protruding from the semiconductor substrate, can be minimized.

Further, a dielectric interlayer is formed on the gate hard mask layer and on the sides of the bit line. Accordingly, the insulation performance between the respective elements can be improved.

Meanwhile, according to yet another embodiment of the present invention, a method of manufacturing a semiconductor device comprises forming recesses in an active region of a semiconductor substrate, forming a gate oxide layer on an entire surface of the semiconductor substrate, including the recesses, forming a first conductive layer over the gate oxide layer, and polishing and etching the first conductive layer, thereby forming a first conductive layer pattern to fill the recesses, forming a gate hard mask layer on an entire surface of the semiconductor substrate, including the first conductive layer pattern, forming contact holes to expose respective regions in which landing plug contacts will be formed in the gate hard mask layer, filling the contact holes with a second conductive layer, thereby forming the landing plug contacts, forming a first dielectric interlayer on an entire surface of the landing plug contacts and the gate hard mask layer, forming a bit line region to expose a region where a bit line will be formed, which belongs to the dielectric interlayer, forming the bit line by filling the bit line region with a third conductive layer, forming a second dielectric interlayer on the bit line and the first dielectric interlayer, forming storage electrode contact holes to expose regions where respective storage electrode contacts will be formed, which belong to the second dielectric interlayer, and forming the storage electrode contacts by filling the storage electrode contact holes with a fourth conductive layer. The first conductive layer, the second conductive layer, the third conductive layer, and the fourth conductive layer are preferably made of the same material.

Further, the forming-a-bit-line-region preferably comprises forming a photoresist pattern on the first dielectric interlayer, and carrying out a lithography process of etching the first dielectric interlayer until the landing plug contacts are exposed.

The forming-the-bit-line preferably comprises depositing a third conductive layer on the bit line region using a CVD, ALD, or PVD method, and polishing the third conductive layer by a polishing and etching process using the first dielectric interlayer as a stopper.

The method further comprises forming a diffusion barrier layer on the gate oxide layer, the gate hard mask layer, the landing plug contact holes, and the storage electrode contact holes. Accordingly, the material of an element which may be made of copper (Cu), from among various elements can be prevented from diffusing.

### BRIEF DESCRIPTION OF THE DRAWINGS

FIG. 1 is a cross-sectional view showing the structure of a semiconductor device according to an embodiment of the present invention; and

FIGS. 2 to 17 are cross-sectional views and plan views showing a method of manufacturing the semiconductor device according to an embodiment of the present invention.

### DESCRIPTION OF EMBODIMENTS

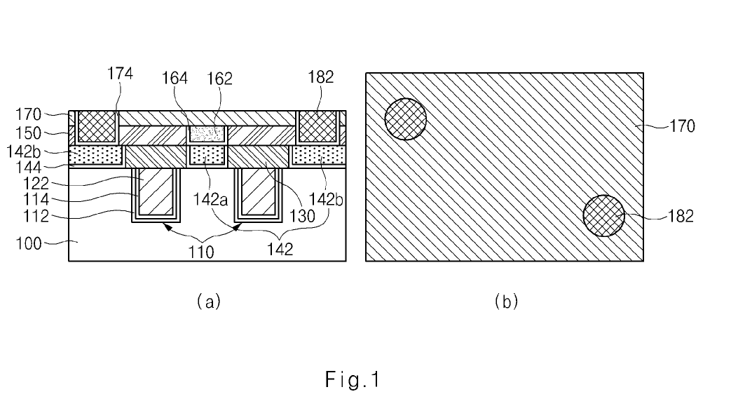

FIG. 1 is a cross-sectional view showing the structure of a semiconductor device according to an embodiment of the present invention. Referring to FIG. 1, recesses 110 are formed in a semiconductor substrate 100, and gate conductive layers 122 are buried in the respective recesses 110. A gate hard mask layer 130 is formed on the gate conductive layers 122. The gate conductive layer 122 and the gate hard mask layer 130 function as a gate electrode.

In the embodiment shown in FIG. 1, the gate is illustrated to be a recess gate formed by etching a surface of the semiconductor substrate 100 to a specific depth and then filling the etched portion with a gate material. Here, as shown in FIG. 1, the gate may be formed so that a top surface of the gate conductive layers 122 is identical to that of the semiconductor substrate 100 while the recess gate is formed.

This is because, in the embodiment shown in FIG. 1, the thickness of landing plug contacts 142a and 142b can be controlled through control of only the thickness of the gate hard mask layer 130. Accordingly, when the gate hard mask layer 130 is thinly formed, the landing plug contacts 142 can also be formed thinly, thereby allowing reduction of the landing plug contacts 142 resistance. Further, if the height of the gate is high, it is difficult to etch the recess for the landing plug contacts 142 down to a surface of the semiconductor substrate 100 at a specific width. In the embodiment of the present invention, however, the gate conductive layers 122 are filled in the respective recesses 110 of the semiconductor substrate 100, and the landing plug contacts 142 is formed to a thickness corresponding to that of the gate hard mask layer 130. Accordingly, a fail in a process of forming the landing plug contacts 142 can be reduced.

A bit line 162 is formed over the landing plug contact 142a placed at the center of the gate structure, which belongs to the landing plug contacts 142a and 142b. Storage electrode contacts 182 are formed over the landing plug contacts 142b placed on the right and left sides of the gate structure. Capacitors (not shown) are formed over the storage electrode contacts 182.

Here, the gate conductive layers 122, the landing plug contacts 142, the bit line 162, and the storage electrode contacts 182 may be made of the same material or a metal including copper (Cu).

Copper (Cu) has a high electrical conductivity, but is difficult to pattern because it is difficult to etch as compared with aluminum (Al). However, if the elements, such as the gate conductive layer and the bit line, are made of copper (Cu) using a damascene process to be described later, the processing speed can be increased greatly and power consumption can be reduced significantly because the resistance of the gate, the bit line, the landing plug, etc. is lowered.

First and second dielectric interlayers 150 and 170 for insulating the elements, such as the gate conductive layers 122, the bit line 162, and the capacitors (not shown), from one another are provided between the respective layers. A gate oxide layer 112 and a diffusion barrier layer 114 are provided between the gate conductive layer 122 and a semiconductor substrate 100. Accordingly, the semiconductor substrate 100 made of a silicon material can be protected, and the material of the gate conductive layer 122 can also be prevented from diffusing into the gate oxide layer 112.

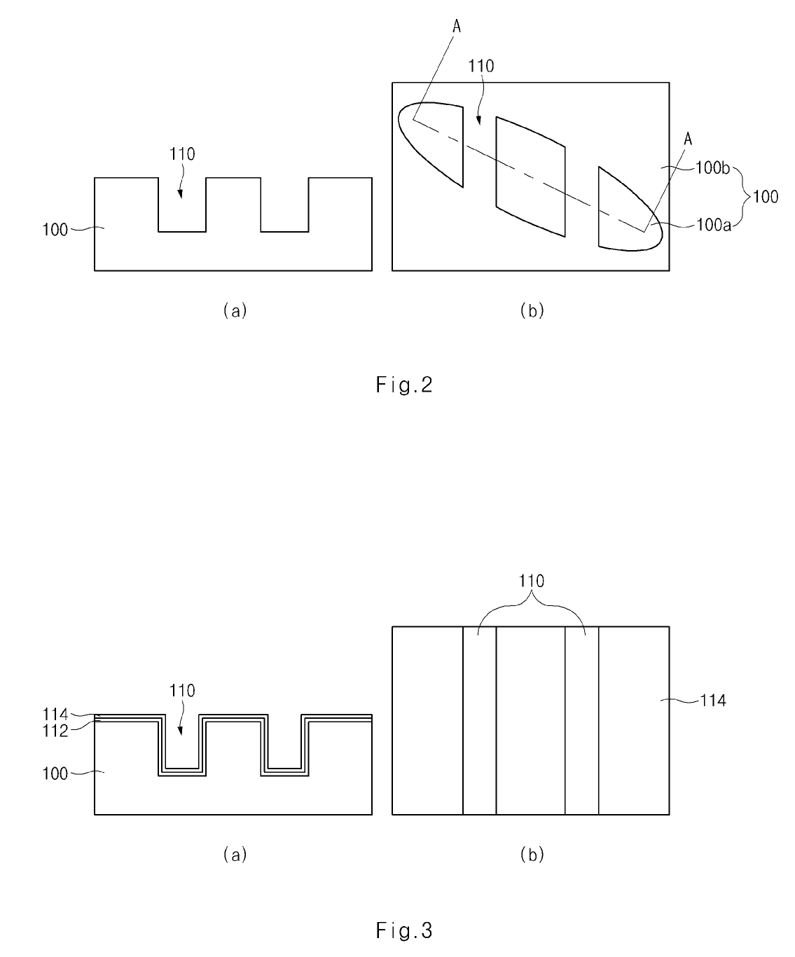

FIGS. 2 to 17 are diagrams showing a method of manufacturing the semiconductor device according to an embodiment of the present invention. The method of manufacturing the semiconductor device according to the embodiment of the present invention is described below in detail with reference to FIGS. 2 to 17. In FIGS. 2 to 17, (a) shows the cross-sectional view of the semiconductor device, and (b) shows the plan view of the semiconductor device. In FIG. 2, (a) shows the cross-sectional view of the semiconductor device taken along line A-A in (b). The same cross-sectional line A-A is used in FIGS. 3 to 17, but not shown.

Referring first to (a) of FIG. 2, the semiconductor substrate 100 is etched to a specific depth using a mask having a specific pattern, thereby forming the recesses 110. Each of the recesses 110 is a region where the gate (i.e., the recess gate) of a transistor will be formed, and a process of forming the recesses 110 may be carried out using dry etching or wet etching.

Referring to (b) of FIG. 2, the semiconductor substrate 100 is divided into an active region 100a and an isolation region 100b. The recesses 110 are formed in the semiconductor substrate 100 including the active region 100a and the isolation region 100b. In an embodiment of the present invention, a semiconductor chip may be made smaller according to the cell design based on 6F2 as compared with the existing 8F2, as shown in (b) of FIG. 2.

Referring to FIG. 3, the gate oxide layer 112 having a specific thickness is formed on the semiconductor substrate 100 including the recesses 110. The diffusion barrier layer 114 is formed on the gate oxide layer 112.

The gate oxide layer 112 may be deposited by a Chemical Vapor Deposition (CVD) method using a high-K material or a PZT material, such as SiO₂, ONO, HfOx, or ZrOx, or a method of heating the semiconductor substrate 100 within a furnace. Alternatively, the gate oxide layer 112 may be deposited by a method of depositing a high-K material, such as Zr or Hf, on the surface of the recesses 110 using Atomic Layer Deposition (ALD).

The diffusion barrier layer 114 may be deposited by a method, such as CVD, Metal-Organic CVD (MOCVD), or ALD, using a material functioning as a barrier for prohibiting the reaction between the gate oxide layer 112 and a gate material (to be filled in the recesses 110 in a subsequent process). In more detail, the diffusion barrier layer 114 prevents a gate material (for the most part, metal) from diffusing into the gate oxide layer 112. The diffusion barrier layer may be made of an oxide-based (MoOx, ZrOx, TaOx, TiOx, RuOx, CrOx, etc.) material, a nitride-based (MoNx, ZrNx, TaNx, TiNx, RuNx, CrNx, etc.) material, or a metal-based (Mo, Zr, Ta, Ti, Ru, Cr, Hf, etc.) material.

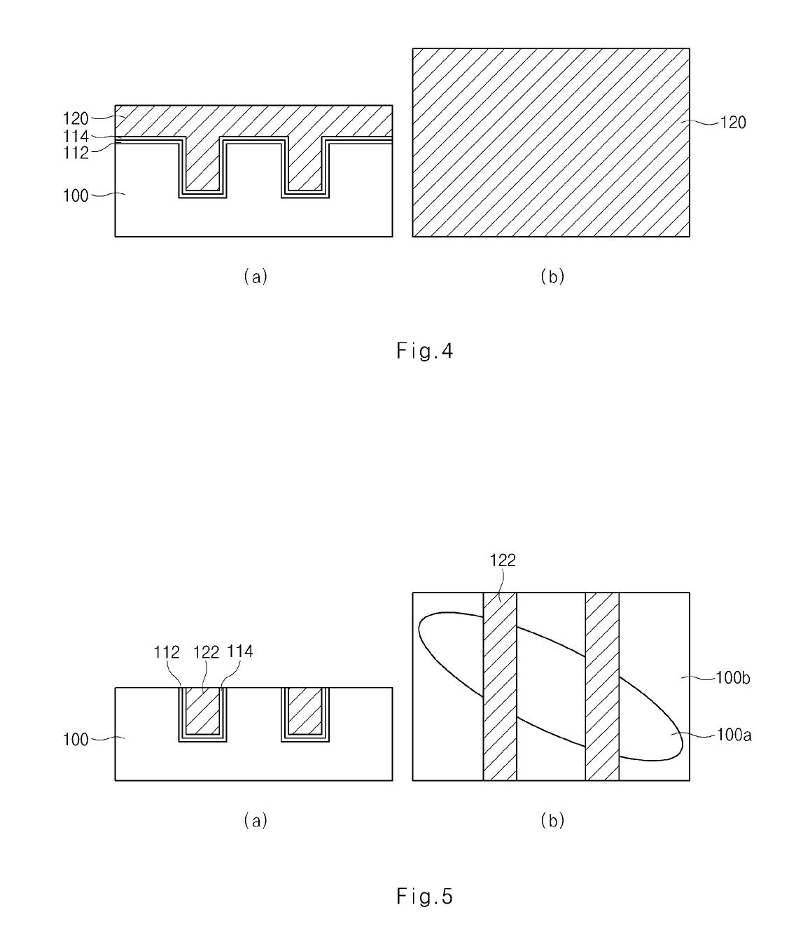

Referring to FIG. 4, a first conductive layer 120 is deposited over the entire surface of the semiconductor substrate 100, including the gate oxide layer 112 and the diffusion barrier layer 114. Referring to FIG. 5, the first conductive layer 120 is etched down to the surface of the semiconductor substrate 100 using a etch process such as Chemical Mechanical Polishing (CMP), thereby forming first conductive layers 122 remaining only in the recesses 110. Each of the first conductive layers 122 becomes the gate conductive layer of a transistor. The diffusion barrier layer 114 and the gate oxide layer 112 formed over the semiconductor substrate 100, other than within the recesses 110, are also removed.

The process of forming the first conductive layers 122 as described above is a so-called damascene process and corresponds to a method of forming a pattern using a material (e.g., copper (Cu)) which is difficult to pattern using a typical dry or wet etch process. The first conductive layer 120 of the present invention may also be made of copper (Cu) or metal including Cu.

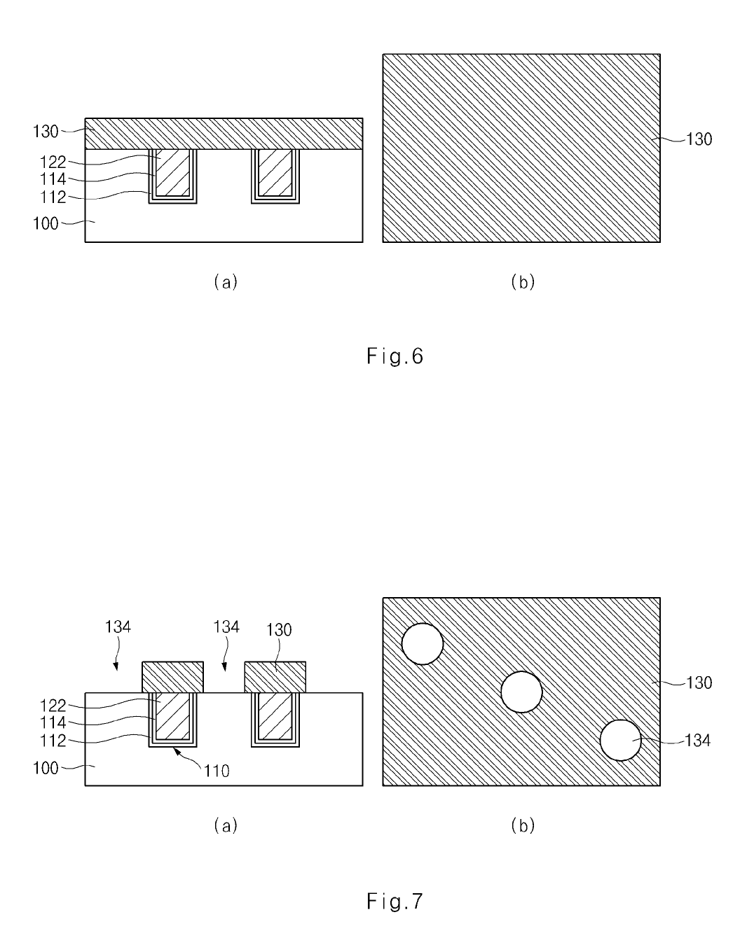

Referring to FIG. 6, the gate hard mask layer 130 is formed on the entire surface of the semiconductor substrate 100 including the first conductive layers 122. The gate hard mask layer 130, as will be described later, functions to protect the gate conductive layers 122 (i.e., the first conductive layers) when the landing plug contacts are formed. The gate hard mask layer 130 may be formed of a nitride layer having a thin thickness of 10 nm to 100 nm using CVD or Physical Vapor Deposition (PVD).

Referring to FIG. 7, landing plug contact holes 134 are formed where a source and a drain will be formed in the surface of the semiconductor substrate 100 (refer to (b) of FIG. 7). In more detail, the landing plug contact holes 134 may be formed by coating a photoresist (not shown) on a surface of the gate hard mask layer 130. The photoresist pattern (not shown) is then formed by an exposure process using a mask to cover/expose the regions where the source/drain will be formed. Then carrying out an etching process on the gate hard mask layer 130 using dry etch or wet etch.

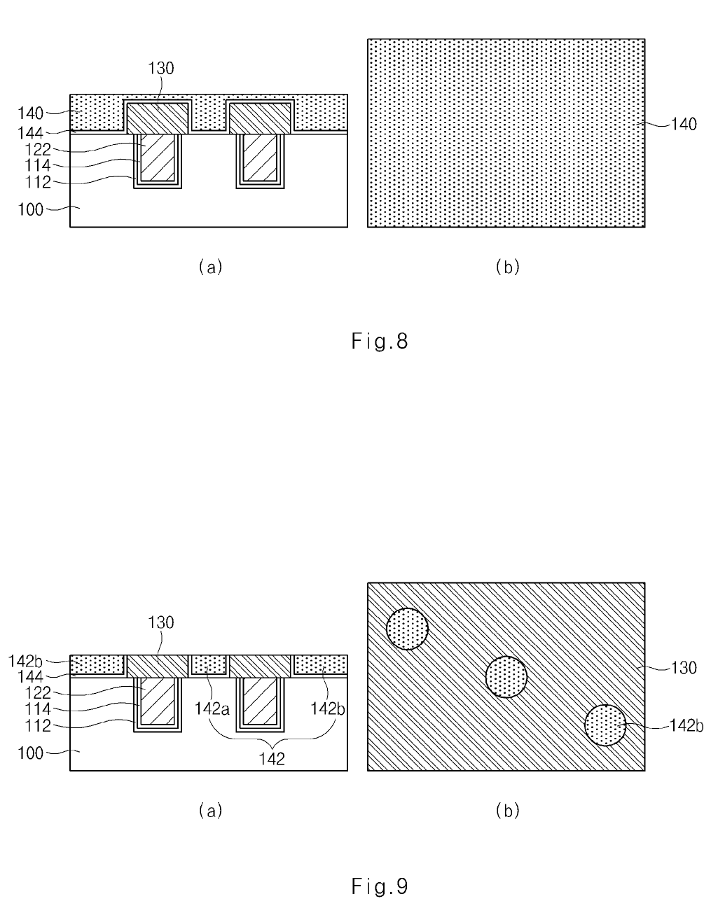

Referring to FIG. 8, a diffusion barrier layer 144 for protecting the landing plug contacts 142 (refer to FIG. 9) is formed on the surface of the gate hard mask layer 130 and the landing plug contact holes 134. A second conductive layer 140 is formed on the entire surface of the diffusion barrier layer 144.

Here, the diffusion barrier layer 144 may be deposited by a method, such as CVD, ALD, or PVD, and may be made of an oxide-based (MoOx, ZrOx, TaOx, TiOx, RuOx, CrOx, etc.) material, a nitride-based (MoNx, ZrNx, TaNx, TiNx, RuNx, CrNx, etc.) material, or a metal-based (Mo, Zr, Ta, Ti, Ru, Cr, Hf, etc.) material. Further, in the case where the diffusion barrier layer 144 is made of the metal-based material, the second conductive layer 140 may be deposited by a method of using the metal-based material as a seed and an adhesive layer and then plating the second conductive layer 140 (e.g., with Cu).

Referring to FIG. 9, the second conductive layer 140 (refer to FIG. 8) is etched by an etching process, such as CMP, using the gate hard mask layer 130 as a stopper (i.e., an etch barrier). Accordingly, the landing plug contacts 142 (i.e., 142a and 142b) are formed in an active region 100a (refer to (b) of FIG. 9). As will be described later, the landing plug contact 142a placed at the center of the gate structure, becomes a bit line node contact, and the landing plug contacts 142b, become storage electrode node contacts. The second conductive layer 140 (i.e., the landing plug contacts 142 after an etching process) may be made of copper (Cu) or a metal including Cu.

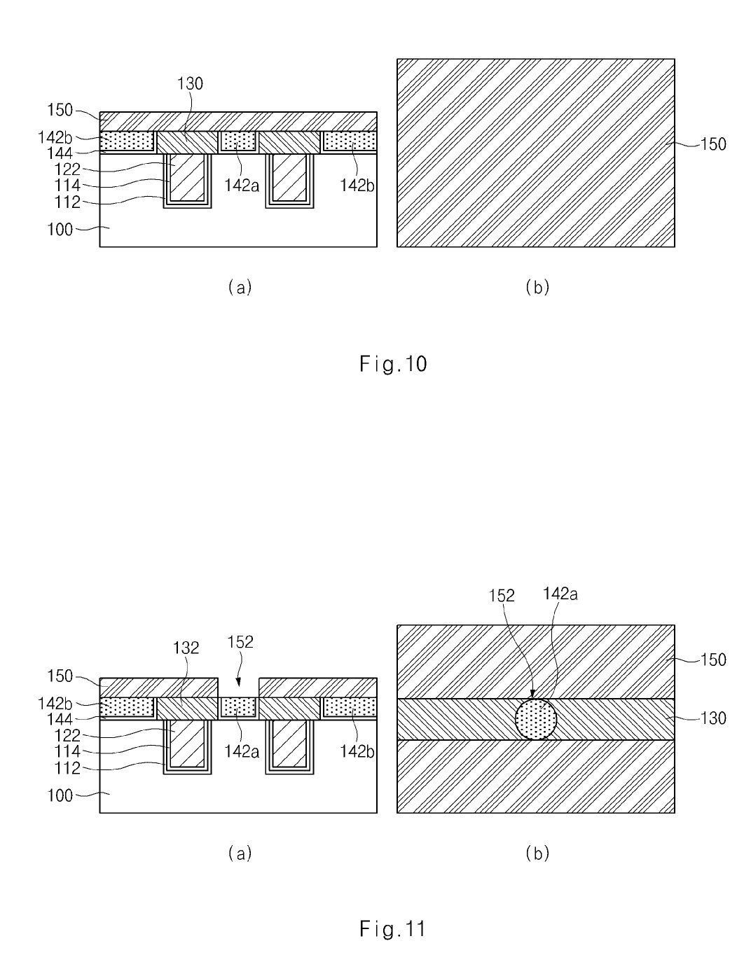

Referring to FIG. 10, the first dielectric interlayer 150 is deposited over the entire surface of the semiconductor substrate 100, including the landing plug contacts 142 and the gate hard mask layer 130. The first dielectric interlayer 150 may be made of an oxide-based (PSG, BOSG, TEOS, HDP, etc.) material, a nitride-based material, amorphous carbon, or diamond-like carbon. The first dielectric interlayer 150, as will be described later, functions to insulate the respective layers so that the landing plug contacts 142a and 142b do not short.

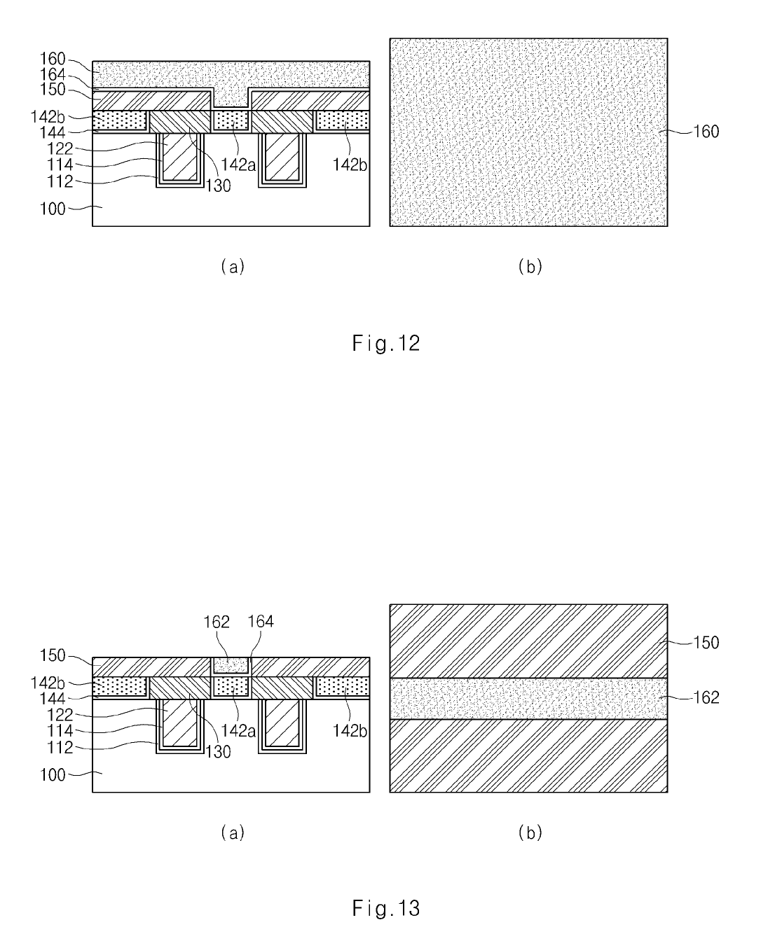

Referring to FIG. 11, a recess (i.e., bit line region 152) is formed in the first dielectric interlayer 150. In more detail, the bit line region 152 may be formed by forming a photoresist pattern on the first dielectric interlayer 150, then carrying out a lithography process and etching the first dielectric interlayer 150 until the landing plug contact 142a is exposed (refer to (b) of FIG. 11). Here, as shown in (b) of FIG. 11, the bit line region 152 is formed perpendicular to the gate conductive layers 122 (i.e., the first conductive layer pattern). Referring to FIG. 12, a diffusion barrier layer 164 is formed over the semiconductor substrate, including the bit line region 152 and the first dielectric interlayer 150. A third conductive layer 160 is deposited on the diffusion barrier layer 164 using a CVD, ALD, or PVD method. Referring to FIG. 13, the bit line 162 is formed by etching the third conductive layer 160 by an etching process, such as CMP, using the first dielectric interlayer 150 as a stopper.

Here, the diffusion barrier layer 164 may be made of an oxide-based (MoOx, ZrOx, TaOx, TiOx, RuOx, CrOx, etc.) material, a nitride-based (MoNx, ZrNx, TaNx, TiNx, RuNx, CrNx, etc.) material, or a metal-based (Mo, Zr, Ta, Ti, Ru, Cr, Hf, etc.) material, in the same manner as the diffusion barrier layer 144. In the case where the diffusion barrier layer 164 is made of a metal-based material, the third conductive layer 160 may be easily deposited by a method of using the metal-based material as a seed and an adhesive layer and then plating the third conductive layer 160 (e.g., with Cu).

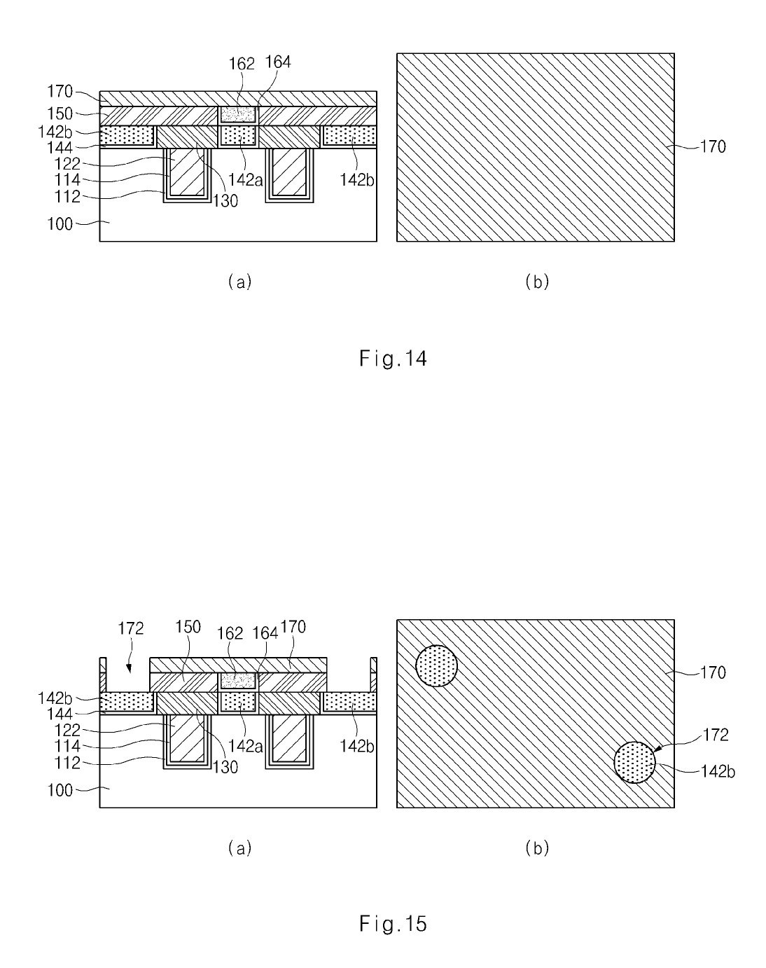

Referring to FIG. 14, the second dielectric interlayer 170 having a specific thickness is deposited on a top surface of the bit line 162 and the first dielectric interlayer 150. Here, the second dielectric interlayer 170 may be made of an oxide-based (PSG, BOSG, TEOS, HDP, etc.) material, a nitride-based material, amorphous carbon, or diamond-like carbon, in the same manner as the first dielectric interlayer 150. The second dielectric interlayer 170 also functions to insulate the respective layers so that the patterns and contacts of the layers do not short.

Referring to FIG. 15, a storage electrode contact hole 172 is formed in the first dielectric interlayer 150 and the second dielectric interlayer 170. The storage electrode contact hole 172 is used to form a connection between a storage electrode bit line region (refer to 142b in FIG. 14) and a storage electrode (not shown). In more detail, the storage electrode contact hole 172 may be formed by forming a photoresist pattern (not shown) over the first dielectric interlayer 150 and the second dielectric interlayer 170 and then carrying out a lithography process and etching the first dielectric interlayer 150 and the second dielectric interlayer 170 until the landing plug contacts 142b are exposed (refer to (b) of FIG. 15).

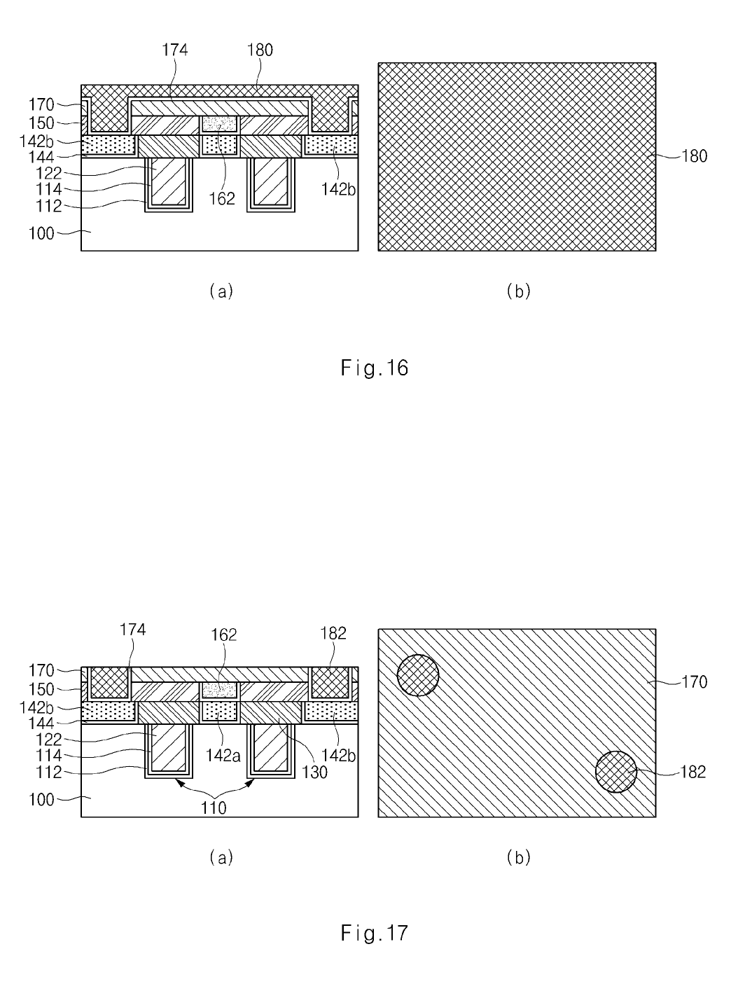

Referring to FIG. 16, a diffusion barrier layer 174 is formed over the semiconductor substrate, including the storage electrode contact hole 172, the second dielectric interlayer 170, and the landing plug contacts 142b. A fourth conductive layer 180 is deposited on the diffusion barrier layer 174. Referring to FIG. 17, the storage electrode contacts 182 are formed by etching the fourth conductive layer 180 by an etching process, such as CMP, using the second dielectric interlayer 170 as a stopper.

Although not shown, a diffusion barrier layer (not shown), made of any one of an oxide-based (MoOx, ZrOx, TaOx, TiOx, RuOx, CrOx, etc.) material, a nitride-based (MoNx, ZrNx, TaNx, TiNx, RuNx, CrNx, etc.) material, and a metal-based (Mo, Zr, Ta, Ti, Ru, Cr, Hf, etc.) material, may be formed on the storage electrode contacts 182 and the second dielectric interlayer 170. The diffusion barrier layer prevents the material of the storage electrode contacts 182 from diffusing. A storage element, such as a capacitor (not shown; in the case of DRAM), and meal wirings may be formed over the diffusion barrier layer (not shown), thereby completing the semiconductor device.

The semiconductor device and the method of manufacturing the same according to the embodiments of the present invention have advantages in that the resistance of a semiconductor device can be minimized, the processing speed can be enhanced, and power consumption can be reduced by forming the gates, the bit line, the bit line contact, and the storage electrode contacts using the same conductive material. Further, according to the embodiments of the present invention, the thickness of a Landing Plug Contact (LPC) layer can be controlled through control of the thickness of the gate hard mask, and the bottom area of the landing plug contact can be widened by thinly forming the gate hard mask. Accordingly, the resistance of the landing plug contact can be reduced, and Selective Epitaxial Growth (SEG) can be applied to a process of forming landing plugs.

According to the semiconductor device and the method of manufacturing the same according to the present invention, since the gates, the bit line, the landing plug contacts, the bit line contact, and the storage electrode contacts are made of the same conductive material, the resistance of a semiconductor device can be minimized, the processing speed can be enhanced, and power consumption can be reduced. Further, the height of a gate structure protruding from the semiconductor substrate can be lowered by making identical the height of a top surface of a gate electrode and the height of a surface of the semiconductor substrate. Accordingly, the thickness of a landing plug contact layer can be made thin. Consequently, the bottom area of the landing plug contact can be widened because the etch depth of the landing plug contact is low. Accordingly, the resistance of the landing plug contact can be reduced, and SEG can be applied to a process of forming landing plugs.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a gate electrode comprising a first conductive layer;
a landing plug contact formed adjacent to the gate electrode and formed of a second conductive layer;
a bit line formed over the landing plug contact and formed of a third conductive layer; and
a storage electrode contact formed over the landing plug contact and the bit line and formed of a fourth conductive layer, wherein the first conductive layer, the second conductive layer, the third conductive layer, and the fourth conductive layer are made of the same material.

2. The semiconductor device according to claim 1, wherein the first conductive layer, the second conductive layer, the third conductive layer, and the fourth conductive layer include material comprising copper (Cu).

3. The semiconductor device according to claim 1, wherein the gate electrode comprises:
the first conductive layer provided within a recess of a semiconductor substrate; and
a gate hard mask layer formed over the first conductive layer.

4. The semiconductor device according to claim 3, further comprising:
a gate oxide layer formed on a surface of the recess; and
a diffusion barrier layer formed on the gate oxide layer.

5. The semiconductor device according to claim 4, wherein the diffusion barrier layer is made of an oxide-based (MoOx, ZrOx, TaOx, TiOx, RuOx, and CrOx) material, a nitride-based (MoNx, ZrNx, TaNx, TiNx, RuNx, and CrNx) material, a metal-based (Mo, Zr, Ta, Ti, Ru, Cr, and Hf) material, or a combination thereof.

6. The semiconductor device according to claim 3, wherein the first conductive layer of the gate is flushed to a top surface of the semiconductor substrate.

7. The semiconductor device according to claim 1, further comprising a dielectric interlayer configured to insulate the first conductive layer, the bit line, and a capacitor from one another.

8. A method of manufacturing a semiconductor device, comprising:
forming a gate electrode in a semiconductor substrate, the gate electrode comprising a first conductive layer;
forming a landing plug contact over a semiconductor substrate adjacent to the gate electrode, the landing plug contact being formed of a second conductive layer;
forming a bit line over the landing plug contact, the bit line being made of a third conductive layer; and
forming a storage electrode contact over the landing plug contact, the storage electrode contacts being made of a fourth conductive layer,
wherein the first conductive layer, the second conductive layer, the third conductive layer, and the fourth conductive layer are made of the same material.

9. The method according to claim 8, wherein the first conductive layer, the second conductive layer, the third conductive layer, and the fourth conductive layer are made of material comprising copper (Cu).

10. The method according to claim 8, wherein the forming-gate-electrode-in-a-semiconductor-substrate comprises:
filling the first conductive layer within a recess of the semiconductor substrate; and
forming a gate hard mask layer over the first conductive layer.

11. The method according to claim 10, further comprising:
forming a gate oxide layer on the recess; and
forming a diffusion barrier layer on the gate oxide layer.

12. The method according to claim 11, wherein the forming-a-diffusion-barrier-layer-on-the-gate-oxide-layer is carried out by a Chemical Vapor Deposition (CVD), Metal-Organic CVD (MOCVD), or Atomic Layer Deposition (ALD) method.

13. The method according to claim 11, wherein the forming-a-gate-oxide-layer is carried out by using a CVD method using a high-K material or a PZT material, a method of heating the semiconductor substrate within a furnace, or a method of depositing a high-K material on a surface of the recesses using ALD and oxidizing the deposited high-K material.

14. The method according to claim 8, wherein a height of the first conductive layer of the gate electrode is flushed to a top surface of the semiconductor substrate.

15. The method according to claim 10, further comprising forming a dielectric interlayer on the gate hard mask layer and on sides of the bit line.

16. A method of manufacturing a semiconductor device, comprising:
forming a recess in an active region of a semiconductor substrate;
forming a gate oxide layer on the recess;
forming a first conductive layer over the gate oxide layer;
removing the first conductive layer until the first conductive layer is flushed to a top surface of the semiconductor substrate;
forming a gate hard mask layer on the first conductive layer pattern flushed to the top surface of the semiconductor substrate;
forming a contact hole in the gate hard mask layer;
filling the contact hole with a second conductive layer to form a landing contact plug;
forming a first dielectric interlayer over the landing contact plug and the gate hard mask layer;
etching the first dielectric interlayer to form a bit line region;
filling the bit line region with a third conductive layer to a bit line;
forming a second dielectric interlayer over the bit line and the first dielectric interlayer;
etching the second dielectric interlayer to form a storage electrode contact hole; and
filling the storage electrode contact hole with a fourth conductive layer to a storage electrode contact,
wherein the first conductive layer, the second conductive layer, the third conductive layer, and the fourth conductive layer are made of the same material.

17. The method according to claim 16, wherein the method further comprises:
forming a photoresist pattern on the first dielectric interlayer;
etching the first dielectric interlayer until the landing contact plug is exposed;
depositing a third conductive layer on the bit line region using a CVD, ALD, or PVD method; and
polishing the third conductive layer using the first dielectric interlayer as a stopper.

18. The method according to claim 16, further comprising forming a diffusion barrier layer on the gate oxide layer, the gate hard mask layer, the landing plug contact holes, and the storage electrode contact holes.

19. The method according to claim 18, wherein the diffusion barrier layer is made of an oxide-based (MoOx, ZrOx, TaOx, TiOx, RuOx, and CrOx) material, a nitride-based (MoNx, ZrNx, TaNx, TiNx, RuNx, and CrNx) material, a metal-based (Mo, Zr, Ta, Ti, Ru, Cr, and Hf) material, or a combination thereof.

20. The method according to claim 16, wherein the first conductive layer, the second conductive layer, the third conductive layer, and the fourth conductive layer are made of material comprising copper (Cu).
